(19) United States
(12) Patent Application Publication
(10) Pub. No.: US 2024/0360543 A1
(43) Pub. Date: Oct. 31, 2024

(54) FILM-FORMING APPARATUS, AND METHOD FOR CLEANING FILM-FORMING APPARATUS

(71) Applicant: TOKYO ELECTRON LIMITED, Tokyo (JP)

(72) Inventors: Masato SHINADA, Tokyo (JP); Naoki KUBOTA, Tokyo (JP)

(21) Appl. No.: 18/573,740

(22) PCT Filed: Jun. 16, 2022
(86) PCT No.: PCT/JP2022/024145

§ 371 Date: Dec. 22, 2023

(30) Foreign Application Priority Data
Jun. 29, 2021 (JP) 2021-108131

(51) Int. Cl. C23C 14/34; C23C 14/50; C23C 14/54; C23C 14/56

(52) U.S. Cl. CPC C23C 14/3407; C23C 14/50; C23C 14/54; C23C 14/564

(57) ABSTRACT

This film-forming apparatus comprises a processing container, a sputtering target provided in the processing container, a pedestal having a mounting surface for mounting of a substrate in the processing container, a shutter member capable of covering the mounting surface, a conveyance mechanism for carrying in and carrying out the shutter member to/from the pedestal, a detection unit that is provided to the conveyance mechanism itself and detects an indicator relating to the presence/absence of the shutter member, and a processing unit for determining whether the shutter member is present/absent with respect to the conveyance mechanism on the basis of the detection result from the detection unit.

### TECHNICAL FIELD

The present disclosure relates to a film forming apparatus, and a method for cleaning a film forming apparatus.

### BACKGROUND

Patent Document 1 discloses a film forming apparatus that forms a film of a target material on a substrate by sputtering the target. Such a film forming apparatus performs cleaning for preparing a surface state of the target (for example, removing a natural oxide film) at an appropriate timing.

In cleaning, discharge (dummy discharge) of a target is performed in a state where no substrate is placed on a placing surface of a placing table. In this case, the film forming apparatus protects the placing surface from substances released during the dummy discharge by covering the placing surface with a shutter member. Specifically, the film forming apparatus performs an operation of making the shutter member stand by at a retreat position during sputtering, locating the shutter member on the placing surface during cleaning, and returning the shutter member to the retreat position after the cleaning.

### PRIOR ART DOCUMENTS

### Patent Documents

Patent Document 1: Japanese Laid-open Patent Publication No. 2002-302763

### SUMMARY

### Problems to Be Resolved by the Invention

The present disclosure provides a technique capable of quickly and stably detecting a shutter member during transfer of the shutter member used for cleaning.

### Means for Solving the Problems

The film forming apparatus according to an embodiment of the present disclosure comprises a processing container; a sputtering target disposed in the processing container; a placing table having a placing surface on which a substrate is placed in the processing container; a shutter member configured to cover the placing surface; a transfer mechanism configured to load and unload the shutter member into and from the placing table; a detection part disposed at the transfer mechanism itself and configured to detect an indicator related to presence or absence of the shutter member; and a processing part configured to determines the presence or absence of the shutter member with respect to the transfer mechanism based on a detection result of the detection part.

Effect of the Invention

In accordance with one embodiment, it is possible to quickly and stably detect a shutter member used for cleaning, during the transfer of the shutter member.

### BRIEF DESCRIPTION OF THE DRAWINGS

FIG. 1 is a schematic plan view showing an example of a configuration of a substrate processing system including a film forming apparatus.

FIG. 2 is a schematic vertical cross-sectional view showing the film forming apparatus.

FIG. 3A is a schematic plan view showing a state in which a shutter member of a shutter mechanism is located at a retreat position.

FIG. 3B is a schematic plan view showing a state in which the shutter member is located at a placing position.

FIG. 4 is a flowchart showing processing flow of a method for cleaning a film forming apparatus.

FIG. 5A is a schematic vertical cross-sectional view of a shutter mechanism part of a film forming apparatus according to a second embodiment.

FIG. 5B is an enlarged vertical cross-sectional view showing a state where the shutter member is normally positioned.

FIG. 5C is an enlarged vertical cross-sectional view showing a state where the shutter member is abnormally positioned.

FIG. 6 is a schematic vertical cross-sectional view showing a shutter mechanism according to a modification.

### DETAILED DESCRIPTION

Hereinafter, embodiments of the present disclosure will be described with reference to the accompanying drawings. Like reference numerals will be given like parts having the same configuration throughout the drawings, and redundant description thereof may be omitted.

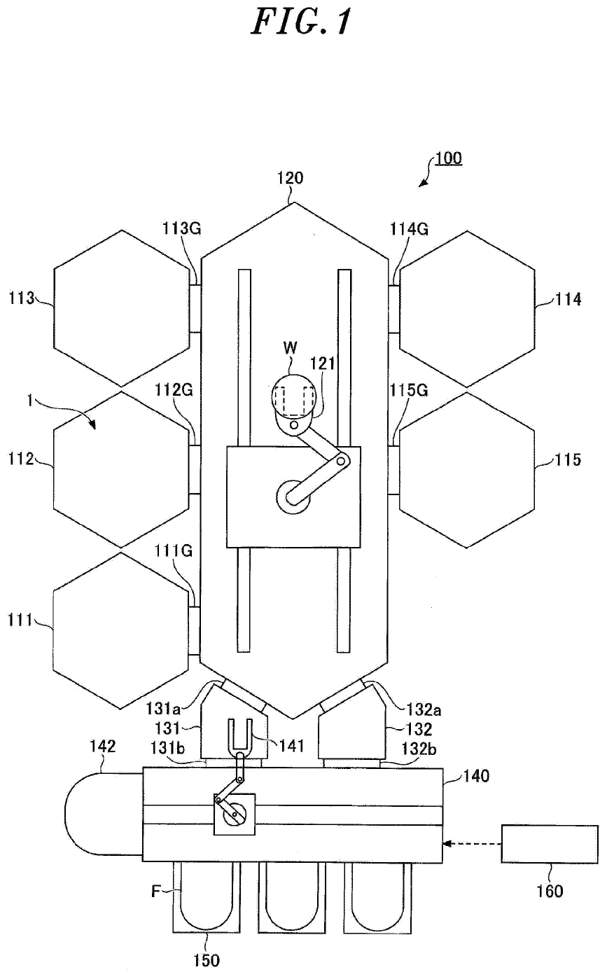

FIG. 1 is a schematic plan view showing a configuration example of a substrate processing system 100 including a film forming apparatus 1. As shown in FIG. 1, the film forming apparatus 1 according to an embodiment is included in the substrate processing system 100 for processing a wafer W that is an example of a substrate.

The substrate processing system 100 is a cluster structure (multi-chamber type) system. The substrate processing system 100 includes a plurality of processing chambers 111 to 115, a vacuum transfer chamber 120, a plurality of load-lock chambers 131 and 132, an atmospheric transfer chamber 140, a load port 150, and a controller 160. The plurality of processing chambers 111 to 115 are decompressed to an appropriate vacuum atmosphere, and perform predetermined processing (cleaning, etching, film formation, or the like) on the wafer W.

In the substrate processing system 100 shown in FIG. 1, the processing chambers 111 to 115 and the vacuum transfer chamber 120 are arranged adjacent to each other, and the wafer W is transferred to each of the processing chambers 111 to 115 via the vacuum transfer chamber 120. The plurality of processing chambers 111 to 115 have gate valves 111G to 115G that allow or block communication with the vacuum transfer chamber 120.

The vacuum transfer chamber 120 of the substrate processing system 100 is connected to a plurality of chambers (the processing chambers 111 to 115 and the load-lock chambers 131 and 132), and is decompressed to a predetermined vacuum atmosphere. The vacuum transfer chamber 120 has therein a vacuum transfer device 121 for transferring the wafer W. The vacuum transfer device 121 performs loading/unloading of the wafer W between each of the processing chambers 111 to 115 and the vacuum transfer chamber 120 by opening/closing the gate valves 111G to 115G of the processing chambers 111 to 115. Further, the vacuum transfer device 121 performs loading/unloading of the wafer W between each of the load-lock chambers 131 and 132 and the vacuum transfer chamber 120 by opening/closing gate valves 131a and 131a of the load-lock chambers 131 and 132.

Each of the load-lock chambers 131 and 132 is disposed between the vacuum transfer chamber 120 and the atmospheric transfer chamber 140, and has an inner atmosphere that is switched between an atmospheric atmosphere and a vacuum atmosphere. The load-lock chambers 131 and 132 are provided with stages (not shown) on which wafers W are placed, gate valves 131a and 132a on the vacuum transfer chamber 120 side, and door valves 131b and 132b on the atmospheric transfer chamber 140 side, respectively. The load-lock chambers 131 and 132 communicate with the vacuum transfer chamber 120, in a vacuum atmosphere, by opening and closing the gate valves 131a and 132a, respectively. Further, the load-lock chambers 131 and 132 communicate with the atmospheric transfer chamber 140, in an atmospheric state, by opening and closing the door valves 131b and 132b, respectively.

The atmospheric transfer chamber 140 is maintained in an atmospheric atmosphere, and a downflow of clean air is generated at the atmospheric transfer chamber 140. The atmospheric transfer chamber 140 includes an atmospheric transfer device 141 for transferring the wafer W, and an aligner 142 for aligning the wafer W.

Further, the load port 150 is disposed on the wall surface of the atmospheric transfer chamber 140. A carrier F containing wafers W or an empty carrier F is attached to the load port 150. A front opening unified pod (FOUP) or the like may be used as the carrier F, for example.

The atmospheric transfer device 141 performs loading/unloading of the wafer W between the load-lock chambers 131 and 132 and the atmospheric transfer chamber 140 by opening/closing the door valves 131b and 132b. Further, the atmospheric transfer device 141 performs loading/unloading of the wafer W between the aligner 142 and the atmospheric transfer chamber 140. Moreover, the atmospheric transfer device 141 performs loading/unloading of the wafer W between the carrier F attached to the load port 150 and the atmospheric transfer chamber 140.

The controller 160 is a control computer including one or more processors, a memory, an input/output interface, and an electronic circuit (all not shown). The controller 160 instructs the processing of the wafer W in each of the processing chambers 111 to 115 and controls the transfer of the wafer W by causing the processor to execute a program and a recipe stored in the memory. Specifically, first, the controller 160 controls the atmospheric transfer device 141 and the vacuum transfer device 121 to adjust the position of the wafer W in the carrier F attached to the load port 150 using the aligner 142, and transfers the wafer W to the vacuum transfer chamber 120 via the load-lock chamber 131.

Further, the controller 160 performs loading/unloading of the wafer W between the vacuum transfer chamber 120 and each of the processing chambers 111 to 115, and performs predetermined processing (cleaning, etching, film formation, or the like) on the wafer W in each of the processing chambers 111 to 115. The film forming apparatus 1 according to one embodiment is installed, as an apparatus for performing film formation, in an appropriate processing chamber among the processing chambers 111 to 115. Hereinafter, the film forming apparatus 1 disposed in the processing chamber 112 will be representatively described.

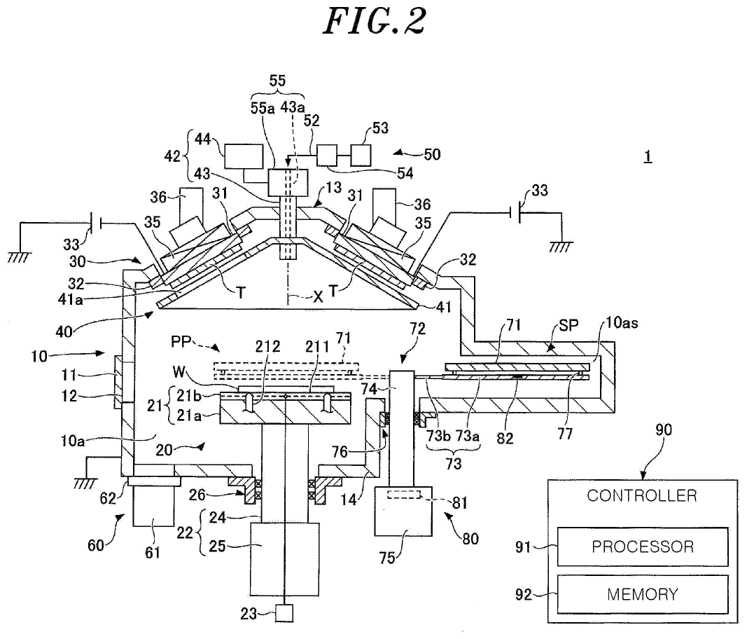

FIG. 2 is a schematic vertical cross-sectional view showing the film forming apparatus 1. As shown in FIG. 2, the film forming apparatus 1 includes the processing container 10 having an inner space 10a. The film forming apparatus 1 includes, as components for performing film formation on the wafer W in the processing container 10, a stage mechanism part 20, a target holding part 30, a target cover part 40, a gas supply part 50, a gas exhaust part 60, and a shutter mechanism part 70. The film forming apparatus 1 further includes a controller 90 for controlling the operations of the individual components.

The processing container 10 of the film forming apparatus 1 is made of aluminum, for example, and is connected to a ground potential. In the film forming apparatus 1, the processing container 10 may be installed in the processing chamber 112, or the inner space 10a of the processing container 10 may constitute the processing chamber 112. The processing container 10 is provided with a loading/unloading port 11 through which the inner space 10a and the outside of the processing container 10 communicate, and a gate valve 12 for opening/closing the loading/unloading port 11. The gate valve 12 corresponds to a gate valve 112G of the processing chamber 112 in FIG. 1. In the film forming apparatus 1, when the gate valve 12 is opened, the loading/unloading of the wafer W through the loading/unloading port 11 is performed by a transfer device (not shown).

The processing container 10 has a processing center axis X that is located at the center of film formation to be performed on the wafer W in the inner space 10a and extends along a vertical direction. The processing center axis X is set to pass through the exact center of the wafer W placed on the stage mechanism part 20. Further, the processing container 10 has a pyramidal portion 13 having a substantially pyramidal shape (for example, a substantially quadrangular pyramidal shape, a conical shape, or the like) at a ceiling portion located above the stage mechanism part 20. The processing center axis X passes through the center (top) of the pyramidal portion 13.

The stage mechanism part 20 includes a placing table 21 disposed in the processing container 10, and a support driving part 22 that supports the placing table 21 to be movable. The placing table 21 has a substantially disc-shaped base portion 21a, and an electrostatic chuck 21b fixed on the base portion 21a.

The base portion 21a is made of aluminum, for example. The base portion 21a is fixed to the upper end of the support driving part 22, and the electrostatic chuck 21b is disposed at a predetermined height position in the inner space 10a. The stage mechanism part 20 may include a temperature control mechanism (not shown) for controlling the temperature of the wafer W placed on the placing table 21 by adjusting the temperature of the base portion 21a.

The electrostatic chuck 21b includes a dielectric film, and an electrode embedded in the dielectric film (both not shown). The upper surface of the electrostatic chuck 21b constitutes a placing surface 211 on which the wafer W is placed in the stage mechanism part 20 (the placing table 21). A DC power supply 23 is connected to the electrode of the electrostatic chuck 21b. The electrostatic chuck 21b generates an electrostatic force at the dielectric film by using the DC voltage supplied to the electrode from the DC power supply 23, and attracts the wafer W placed on the placing surface 211. The center of the placing surface 211 coincides with the processing center axis X.

The placing table 21 is provided with a plurality of (for example, three) lift pins 212 that protrude from the placing surface 211 to support the wafer W, and a vertical movement part (not shown) for vertically moving the plurality of lift pins 212. In the stage mechanism part 20, when the wafer W is transferred to the inner space 10a by the vacuum transfer device 121, the lift pins 212 protrude from the placing surface 211 by the vertical movement part, and the wafer W is received at the upper ends of the lift pins 212. Further, in the stage mechanism part 20, the lift pins 212 retreat toward the placing surface 211 by the vertical movement part, and the wafer W is placed on the placing surface 211. On the other hand, in the case of unloading the wafer W, the lift pins 212 protrude upward to separate the wafer W from the placing surface 211, and the wafer W is delivered to the vacuum transfer device 121.

The support driving part 22 has a columnar support shaft 24 for holding the base portion 21a, and an operation part 25 for operating the support shaft 24. The support shaft 24 extends along the vertical direction, and extends from the inner space 10a of the processing container 10 to the outside of the processing container 10 through a bottom portion 14. The shaft center of the support shaft 24 overlaps the processing center axis X.

The operation part 25 is disposed outside the processing container 10, and holds the lower end side of the support shaft 24. The operation part 25 rotates the support shaft 24 around the processing center axis X, and raises and lowers (vertically moves) the support shaft 24 under the control of the controller 90. The placing table 21 rotates and vertically moves in the processing container 10 by the operation of the operation part 25.

Further, the stage mechanism part 20 has a sealing structure 26 between the bottom portion 14 of the processing container 10 and the support shaft 24. The sealing structure 26 seals a gap therebetween while allowing the movement of the support shaft 24. The sealing structure 26 may be, e.g., magnetic fluid seal.

The target holding part 30 of the film forming apparatus 1 holds a plurality of targets T, which are cathode targets, at positions spaced upward from the placing table 21. The target holding part 30 includes metal holders 31 for respectively holding the targets T, and insulating members 32 for supporting the holders 31 by fixing the outer peripheral portions of the holders 31.

Each target T held by each holder 31 is made of a metal material containing a film forming substance, and has a rectangular flat plate shape. Further, some or all of the targets T may be made of the same metal material.

Each holder 31 is formed in a rectangular shape that is considerably larger than the target T in plan view. The holders 31 are fixed to the inclined surface of the pyramidal portion 13 via the insulating members 32. Therefore, the holders 31 hold the surfaces (the sputtering surfaces exposed to the inner space 10a) of the targets T in a state where they are inclined with respect to the processing center axis X.

Further, the target holding part 30 electrically connects a plurality of power supplies 33 to the targets T held by the holders 31. Each of the power supplies 33 applies a negative DC voltage to the target T connected thereto. The power supplies 33 may be a single power supply that selectively applies a voltage to the targets T.

Further, the target holding part 30 includes a plurality of magnets 35 and magnet operation parts 36 for operating the corresponding magnets 35 on the rear surface sides of the holders 31 (on the side opposite to the holding surfaces of the targets T). The plurality of magnets 35 apply magnetic field H to the targets T, thereby inducing plasma to the targets T. The magnets 35 are arranged such that the bottom surfaces (facing surfaces) of the magnets 35 become parallel to the holders 31 and the targets T in line with the inclination of the holders 31 fixed to the pyramidal portion 13.

The magnet operation part 36 reciprocates the magnet 35 in parallel to the extension direction of the target T (the holder 31). For example, the magnet operation part 36 includes a rail extending in the longitudinal direction of the target T, and a movable body that holds the magnet 35 and is movable along the rail (all not shown).

The target cover part 40 of the film forming apparatus 1 includes an umbrella body 41 disposed in the processing container 10, and an umbrella body driving part 42 for supporting the umbrella body 41 to be movable. The umbrella body 41 is disposed between the plurality of targets T and the placing table 21. The umbrella body 41 is formed in a pyramidal shape that is substantially parallel to the inclined surface of the pyramidal portion 13 of the processing container 10, and thus can face the sputtering surfaces of the plurality of targets T. Further, the umbrella body 41 has one opening 41a that is slightly larger than the target T. The opening 41a is disposed to face one of the plurality of targets T by the umbrella body driving part 42. Accordingly, the umbrella body 41 exposes only a selected target Ts to the placing table 21, and prevents the other targets T from being exposed.

The umbrella body driving part 42 has a columnar rotation shaft 43, and a rotation part 44 that rotates the rotation shaft 43. The axial line of the rotation shaft 43 overlaps the processing center axis X of the processing container 10. The rotation shaft 43 extends along the vertical direction, and fixes the center (apex) of the umbrella body 41 at the lower end thereof. The rotation shaft 43 projects to the outside of the processing container 10 through the center of the pyramidal portion 13.

The rotation part 44 is disposed outside the processing container 10, and rotates the rotation shaft 43 relative to the upper end (a connector 55a) that is holding the rotation shaft 43 via a rotation transmitting part (not shown). Accordingly, the rotation shaft 43 and the umbrella body 41 rotate around the processing center axis X. Hence, the target cover part 40 can adjust the circumferential position of the opening 41a under the control of the controller 90, and can make the opening 41a face the selected target Ts to be sputtered.

The gas supply part 50 of the film forming apparatus 1 is disposed at the pyramidal portion 13 and supplies an excitation gas. Further, the gas supply part 50 may include an oxidizing gas part (not shown) for supplying, in addition to an excitation gas, an oxidizing gas for oxidizing a metal (sputtered particles) deposited on the wafer W.

The gas supply part 50 includes a line 52 through which a gas flows outside the processing container 10, and also includes a gas source 53, a flow rate controller 54, and a gas introducing part 55 disposed in that order from the upstream side toward the downstream side of the line 52. The gas source 53 stores an excitation gas (e.g., Ar gas), and discharges the gas into the line 52. The flow rate controller 54 is, e.g., a mass flow controller or the like, and adjusts the flow rate of a gas supplied into the processing container 10. The gas introducing part 55 introduces a gas into the processing container 10 from the outside. The gas introducing part 55 includes the connector 55a connected to the line 52 outside the processing chamber 10, and a gas channel 43a formed in the rotation shaft 43 of the target cover part 40.

The gas exhaust part 60 of the film forming apparatus 1 includes a decompression pump 61, and an adapter 62 for fixing the decompression pump 61 to the bottom portion 14 of the processing chamber 10. The gas exhaust part 60 decreases a pressure in the inner space 10a of the processing container 10 under the control of the controller 90.

The individual components of the substrate processing system 100 and the film forming apparatus 1 described above are the same as those of the film forming apparatus 1 according to the present disclosure. Next, the configuration of the shutter mechanism part 70 of the film forming apparatus 1 according to a first embodiment will be described with reference to FIGS.

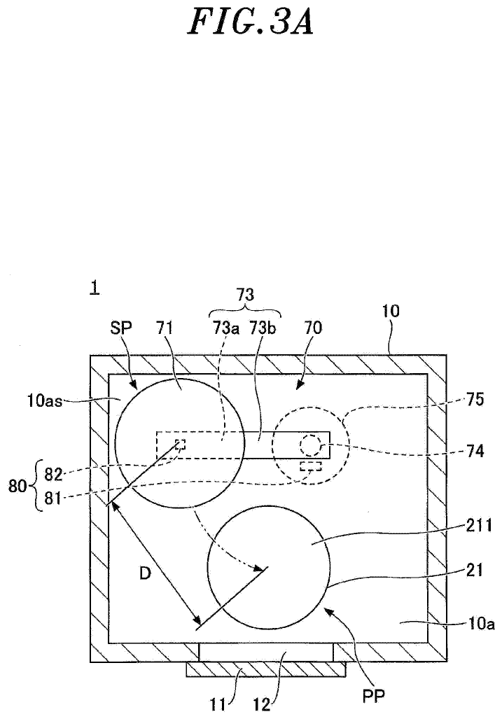

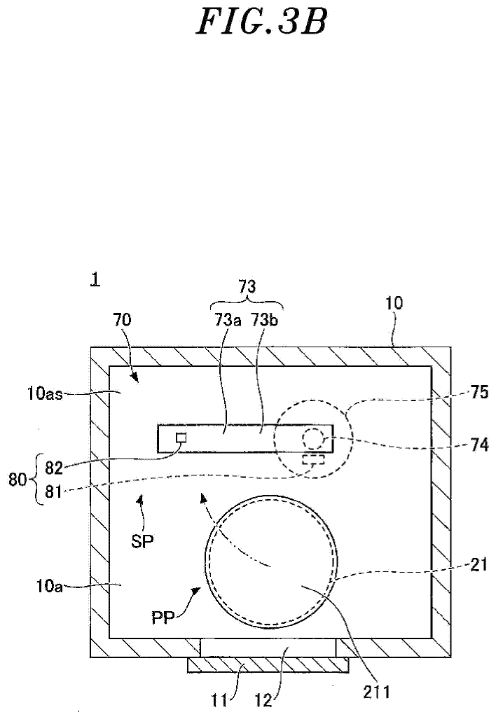

2, 3A and 3B. FIG. 3A is a schematic plan view showing a state in which the shutter member 71 of the shutter mechanism is located at a retreat position SP. FIG. 3B is a schematic plan view showing a state in which the shutter member 71 is located at a placing position PP.

### First Embodiment

The shutter mechanism part 70 is a mechanism part for protecting the placing table 21 at the time of performing dummy discharge during the cleaning (conditioning of the target T) of the processing container 10. The shutter mechanism part 70 includes a disc-shaped shutter member 71 having an appropriate thickness, and a transfer mechanism 72 for loading and unloading the shutter member 71 with respect to the placing table 21.

The shutter member 71 of the shutter mechanism part 70 covers the entire placing surface 211 of the placing table 21, so that the placing surface 211 is not exposed during the dummy discharge. Therefore, the shutter member 71 has a perfect circular shape in plan view to correspond to (be similar to) the shape of the placing surface 211. The diameter of the shutter member 71 is set to be the same as or slightly larger than the diameter of the placing surface 211 of the placing table 21. The diameter of the shutter member 71 is preferably within a range of about 200 mm to 500 mm, for example. In one embodiment, the upper surface and the bottom surface of the shutter member 71 is formed to be flat.

The material of the shutter member 71 is not particularly limited as long as it has an appropriate rigidity, and may be stainless steel (SUS), aluminum, or the like. In the first embodiment, a magnetic SUS made of a magnetic material is applied to the shutter member 71 so that a detection part 80 to be described later detects the magnetic change caused by the presence/absence of the shutter member 71.

The shutter member 71 is detachably supported by the transfer mechanism 72. When the shutter member 71 is transferred onto the placing table 21 by the transfer mechanism 72, the shutter member 71 covers the placing surface 211 while being separated from the transfer mechanism 72.

In the shutter mechanism part 70, the shutter member 71 is transferred by the transfer mechanism 72 to the placing position PP where the shutter member 71 can be delivered at a position above the placing table 21 and the retreat position SP retreated from the placing table 21. Therefore, a part of the sidewall of the processing container 10 is formed to protrude outward in the horizontal direction, and the processing container 10 has, at the inner side (the inner space 10a) of the protruding portion, a retreat section 10as corresponding to the retreat position SP of the shutter member 71.

The retreat position SP is spaced apart from the placing position PP in the horizontal direction so that the placing surface 211 is exposed upward in a state where the shutter member 71 is retreated. A distance D from the center of the placing position PP (the center of the placing surface 211) to the center of the retreat position SP (the center of the retreated shutter member 71) is preferably set to be 1.1 to 2 times the diameter of the shutter member 71, for example. Accordingly, the film forming apparatus 1 can scale down the processing container 10 using the configuration having the retreat section 10as.

The transfer mechanism 72 of the shutter mechanism part 70 includes a support arm 73 for supporting the shutter member 71, a shaft portion 74 connected to the support arm 73, and a rotation device 75 for rotating the shaft portion 74. Further, the shutter mechanism part 70 includes a sealing structure 76 between the bottom portion 14 of the processing container 10 and the shaft portion 74 to seal a gap therebetween while allowing the rotation of the shaft portion 74. The sealing structure 76 may be, for example, a magnetic fluid seal.

The support arm 73 includes a support main body 73a for supporting the shutter member 71, and a connection bar 73b extending between the support main body 73a and the shaft portion 74. The support main body 73a and the connection bar 73b operate together.

The support main body 73a is formed in an appropriate shape that allows the shutter member 71 to be supported and avoids interference with the plurality of lift pins 212 of the placing table 21 in plan view, and supports the inner side rather than the outer peripheral portion of the shutter member 71. The upper surface and the bottom surface of the support main body 73a extend in parallel to the placing surface 211 (along the horizontal direction).

The support main body 73a includes a plurality of (for example, three) contact terminals 77 that protrude from the upper surface of the support main body 73a and is brought into contact with the bottom surface of the shutter member 71 (see FIG. 2). In order to stably support the shutter member 71, the contact terminals 77 are spaced apart from the center of the support main body 73a by a predetermined radius and are arranged at substantially equal intervals along the circumferential direction. Each contact terminal 77 is made of, for example, a resin material that is softer than the shutter member 71.

The connection bar 73b has a rigidity that allows the support main body 73a to be supported in the horizontal direction. The shaft portion 74 is firmly fixed to one end of the connection bar 73b. The support arm 73 moves the support main body 73a and the shutter member 71 in an arc shape using the connection bar 73b extending from the shaft portion 74.

The shaft portion 74 extends along a direction (vertical direction) parallel to the processing center axis X, and supports the connection bar 73b at the upper end thereof. The shaft portion 74 protrudes to the outside of the processing container 10, and is connected to the rotation device 75 outside the processing container 10.

The rotation device 75 includes a motor 75a serving as a driving source, and a gear mechanism 75b disposed between the rotation shaft of the motor 75a and the lower end of the shaft portion 74, and rotates the shaft portion 74 at an appropriate rotation speed and rotation angle. The motor 75a is connected to the controller 90 via an operation driver (not shown), and the rotation angle thereof is controlled under the control of the controller 90. For example, the gear mechanism 75b reduces the rotation speed of the motor 75a. The rotation device 75 preferably has a limiter function for setting the rotation angle of the shaft portion 74 (i.e., the support arm 73) to be within a range from the placing position PP to the retreat position SP.

Further, in the shutter mechanism part 70, the transfer mechanism 72 itself is provided with the detection part 80 for detecting an indicator related to the presence or absence of the shutter member 71. In one embodiment, the detection part 80 may be a torque sensor 81 disposed at the rotation device 75, and a magnetic sensor 82 disposed at the support arm 73. The detection part 80 may be only one of the torque sensor 81 and the magnetic sensor 82.

The torque sensor 81 may be, for example, a non-contact type or a contact type sensor that is disposed around the rotation shaft of the motor 75a and continuously detects the torque of the rotation shaft. In other words, the torque obtained when the shutter member 71 is supported by the support arm 73 is larger than the torque obtained when the shutter member 71 is not supported by the support arm 73. Therefore, in the film forming apparatus 1, whether or not the shutter member 71 is supported by the support arm 73 (the presence or absence of the shutter member 71 exists) can be detected by acquiring the torque of the torque sensor 81 as an indicator. Alternatively, the torque sensor 81 may be an ammeter disposed between the rotation device 75 and the operation driver. The controller 90 can recognize that the shutter member 71 is supported by the support arm 73 based on the increase in the current value of the ammeter.

The magnetic sensor 82 may be, for example, a non-contact type sensor that is disposed at the center of the support main body 73a and continuously detects the magnetic change. In other words, the magnetic sensor 82 detects different magnetisms (detects the magnetic change), i.e., the magnetism obtained when the shutter member 71 is supported by the support arm 73 and the magnetism obtained when the shutter member 71 is not supported by the support arm 73. Therefore, even if the film forming apparatus 1 acquires, as an indicator, the magnetic change of the magnetic sensor 82, it is possible to detect whether or not the shutter member 71 is supported by the support arm 73. The number and position of the magnetic sensor 82 are not particularly limited as long as they can appropriately detect the presence or absence of the shutter member 71 on the support main body 73a.

The controller 90 of the film forming apparatus 1 is a control computer including one or more processors 91, a memory 92, an input/output interface (not shown), and an electronic circuit (not shown). One or more processors 81 may be combination of one or more of a central processing unit (CPU), an application specific integrated circuit (ASIC), a field-programmable gate array (FPGA), and a circuit formed of multiple discrete semiconductors. The memory 92 includes a nonvolatile memory and a volatile memory, and constitutes a storage part of the controller 80. Some of the memory 92 may be built in one or more processors 91.

The processor 91 executes a program stored in the memory 92 to perform film formation (sputtering for depositing a metal on the wafer W) of the film forming apparatus 1. During the film formation, the processor 91 controls the operations of individual components of the film forming apparatus 1 based on the recipe stored in the memory 92.

In the film forming process, the processor 91 causes the shutter member 71 of the shutter mechanism part 70 to stand by at the retreat position SP, and exposes the placing surface 211 upward in plan view. Accordingly, in the substrate processing system 100, when the wafer W is transferred into the processing container 10, the wafer W is placed on the placing surface 211 with high accuracy. Then, the processor 91 supplies an excitation gas into the processing container 10 using the gas supply part 50, and controls the gas exhaust part 60 to set a pressure in the processing container 10 to a predetermined pressure. Further, the processor 91 controls the rotation of the umbrella body driving part 42 to make the opening 41a face the target T, and controls the magnet operation part 36 to operate each magnet 35. The controller 90 controls the power supply 33 to apply a negative DC voltage to the targets T to generate plasma, and performs sputtering in which the plasma collides with the targets T. The targets T collided with the plasma release a metal, as sputtered particles, into the inner space 10a, and the sputtered particles are deposited on the wafer W, thereby forming a film on the wafer W.

Further, the processor 91 performs cleaning (conditioning the targets T) of the processing container 10, at appropriate timing different from that of the film forming process or based on a user's operation. In this case, the processor 91 controls the transfer mechanism 72 to move the shutter member 71 standing by at the retreat position SP to the placing position PP, and the placing surface 211 of the placing table 21 is covered with the shutter member 71. The film forming apparatus 1 performs dummy discharge in a state where the placing table 21 is protected by the shutter member 71, thereby preventing particles from being adhered to the placing surface 211 during the dummy discharge and preparing the surface state of the target T. The cleaning operation will be described in detail later.

Further, the processor 91 recognizes each step in the cleaning, and determines the presence of absence of the shutter member 71 on the support arm 73 based on the detection result of the detection part 80 in each step. For example, the processor 91 has a torque threshold corresponding to the torque detected by the torque sensor 81, and determines whether the detected torque is greater than or equal to the torque threshold. When the detected torque is greater than or equal to the torque threshold value, it is determined that the shutter member 71 exists on the support arm 73. When the detected torque is less than the torque threshold value, it is determined that the shutter member 71 does not exist on the support arm 73.

Similarly, the processor 91 has a magnetic threshold corresponding to the detected magnetism of the magnetic sensor 82, and determines whether the detected magnetism is greater than or equal to the magnetic threshold. When the detected magnetism is greater than or equal to the magnetic threshold, it is determined that the shutter member 71 exists on the support arm 73. When the detected magnetism is less than the magnetic threshold, it is determined that the shutter member 71 does not exist on the support arm 73.

When it is determined that the shutter member 71 exists based on both the determination result of the detected torque of the torque sensor 81 and the determination result of the detected magnetism of the magnetic sensor 82, the processor 91 recognizes that the shutter member 71 is supported by the support arm 73. On the other hand, when it is determined that the shutter member 71 does not exist based on both the determination result of the detected torque of the torque sensor 81 and the determination result of the detected magnetism of the magnetic sensor 82, the processor 91 recognizes that the shutter member 71 is not supported by the support arm 73. Further, the processor 91 may determine the failure of the detection part 80 when one of the determination result of the detected torque of the torque sensor 81 and the determination result of the detected magnetism of the magnetic sensor 82 indicates that the shutter member 71 exists and the other determination result indicates that the shutter member 71 does not exist. Alternatively, the processor 91 may determine the presence or absence of the shutter member 71 by using only one of the determination result of the detected torque of the torque sensor 81 and the determination result of the detected magnetism of the magnetic sensor 82.

When it is determined that the shutter member 71 does not exist at the timing in which the shutter member 71 is supported by the support arm 73, the processor 91 notifies a user of an error indicating that the shutter member 71 is not supported. Accordingly, the user can quickly deal with the error of the film forming apparatus 1. When the processor 91 determines that the shutter member 71 does not exist at the timing in which the shutter member 71 is received from the placing table 21, the processor 91 may allow the shutter member 71 to be received from the placing table 21 to the support arm 73 again (multiple times). Accordingly, in the film forming apparatus 1, it is possible to increase the possibility that the shutter member 71 is supported by the support arm 73 without error notification.

The film forming apparatus 1 according to one embodiment is basically configured as described above. Hereinafter, the operation and effects thereof will be described.

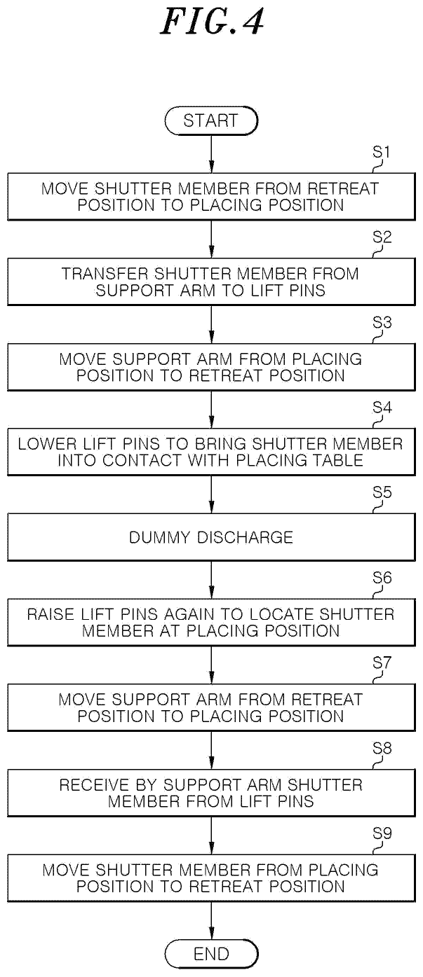

FIG. 4 is a flowchart showing processing flow of a cleaning method for the film forming apparatus 1. As shown in FIG. 4, in the case of performing the cleaning method, first, the controller 90 of the film forming apparatus 1 controls the operation of the transfer mechanism 72 to move (load) the shutter member 71 from the retreat position SP to the placing position PP (step S1: loading process). In this case, the controller 90 controls the rotation device 75 to rotate the support arm 73 until the support main body 73a of the support arm 73 reaches the placing position PP (see also FIG. 3A).

In the loading process, the controller 90 sets a flag indicating the loading process to control the detection part 80 to perform detection, and determines whether or not the shutter member 71 is supported by the support arm 73 (whether or not the shutter member 71 exists) based on the detected torque and the detected magnetism, for example. In the loading process, a state in which the shutter member 71 is supported by the support arm 73 is a normal state. Therefore, when it is determined that the shutter member 71 exists, the controller 90 continues the loading process, and when it is determined that the shutter member 71 does not exist, the controller 90 recognizes transfer abnormality of the shutter member 71 and notifies a user of the abnormality. In this case, for example, the controller 90 determines, at the initial stage of the loading process, that the shutter member 71 is detached from the support arm 73 and notifies the user of the state, and determines, at the intermediate or subsequent stage of the loading process, that the shutter member 71 has fallen and notifies the user of the state. Accordingly, when the abnormality has occurred, the user can immediately deal with the abnormality.

When the shutter member 71 is moved to the placing position PP, the controller 90 raises the lift pins 212 from the placing table 21 and transfers the shutter member 71 from the support arm 73 to the lift pins 212 (step S2: delivery process). Also in this delivery process, the controller 90 can determine whether or not the support main body 73a has been successfully delivered to the lift pins 212 based on the change in the detected magnetism of the magnetic sensor 82, for example.

Next, the controller 90 operates the transfer mechanism 72 in a state where the shutter member 71 does not exist to move the support arm 73 from the placing position PP to the retreat position SP (step S3: retreat process, see also FIG. 3B). Also in this retreat process, the controller 90 sets a flag indicating the retreat process to control the detection part 80 to perform detection, and determines whether or not the shutter member 71 is supported by the support arm 73 based on the detected torque and the detected magnetism. In the retreat process, a state in which the shutter member 71 is not supported by the support arm 73 is a normal state.

Therefore, when it is determined that the shutter member 71 does not exist, the controller 90 continues the retreat process, and when it is determined that the shutter member 71 exists, the controller 90 recognizes delivery abnormality of the shutter member 71 and notifies a user of the abnormality. When the controller 90 recognizes the delivery abnormality of the shutter member 71, the controller 90 may immediately return to step S2 to retry the delivery process, or may notify a user of the abnormality after the delivery process is executed multiple times. Accordingly, the user can quickly recognize the failure of the lift pins 212 or the like.

Next, the controller 90 lowers the lift pins 212 to bring the shutter member 71 into contact with the placing table 21, and the entire surface of the placing surface 211 is covered with the shutter member 71 (step S4). Then, the controller 90 controls the power supply 33 to apply an appropriate DC voltage to a desired target T to generate plasma and allow positive ions in the plasma to collide with the surface of the target T (step S5: dummy discharge process). Accordingly, sputtered particles are released from the target T, and the surface of the target T is prepared (natural oxide film is removed). Since the placing surface 211 is covered with the shutter member 71 during the dummy discharge in the film forming apparatus 1, sputtered particles released from the targets T can be prevented from being deposited on the placing surface 211.

After the dummy discharge process, the controller 90 raises the lift pins 212 again to locate the shutter member 71 at the placing position PP, thereby allowing the shutter member 71 to be received by the transfer mechanism 72 (step S6). Then, the controller 90 operates the transfer mechanism 72 to move the support arm 73 from the retreat position SP to the placing position PP (step S7: relocation process). In the relocation process, the support main body 73a of the support arm 73 is located between the placing surface 211 and the bottom surface of the shutter member 71.

Thereafter, the controller 90 lowers the plurality of lift pins 212 so that the support main body 73a of the support arm 74 can receive the shutter member 71 from the plurality of lift pins 212 (step S8: receiving process). Also in this receiving process, the controller 90 can determine whether or not the shutter member 71 has been normally received based on, e.g., the change in the detected magnetism of the magnetic sensor 82.

Then, in a state where the shutter member 71 is supported by the support arm 73, the controller 90 operates the transfer mechanism 72 to move (unload) the shutter member 71 from the placing position PP to the retreat position SP (step S9: unloading process). In this case, the controller 90 controls the rotation device 75 to rotate the support arm 73 until the support main body 73a of the support arm 73 reaches the retreat position SP.

Also in this unloading process, the controller 90 also sets a flag indicating the unloading process to control the detection part 80 to perform detection, and determines whether the shutter member 71 is supported by the support arm 73 based on the detected torque and the detected magnetism. In the unloading process, a state in which the shutter member 71 is supported by the support arm 73 is a normal state. Therefore, when it is determined that the shutter member 71 exists, the controller 90 continues the unloading process, and when it is determined that the shutter member 71 does not exist, the controller 90 recognizes the transfer abnormality of the shutter member 71 and notifies a user of the abnormality. Accordingly, when the abnormality has occurred, the user can immediately deal with the abnormality appropriately.

When the shutter member 71 is returned to the retreat position, the control part 90 terminates the cleaning. As described above, the controller 90 can accurately determine the presence or absence of the shutter member 71 using the detection part 80 of the transfer mechanism 72 itself, during the transfer of the shutter member 71 or at the time of delivering or receiving the shutter member 71 in the cleaning.

In the conventional film forming apparatus, whether or not the shutter member is supported by the support arm has been determined based on the detection of the shutter member by an optical sensor (photoelectric sensor) installed at the retreat section 10as. The application of such an optical sensor complicates the structure of the retreat section 10as, and causes scaling up of the processing container 10. Further, in the configuration in which the optical sensor is provided at the retreat position SP, it is not possible to determine the presence or absence of the shutter member until the shutter member is returned to the retreat position SP, so that the detection timing of the shutter member is delayed.

On the other hand, in the film forming apparatus 1 in which the detection part 80 is provided at the transfer mechanism 72 itself, the retreat section 10as where the shutter member 71 retreats can be simplified, which makes it possible to facilitate the scaling down of the processing container 10. Further, in the film forming apparatus 1, the presence or absence of the shutter member 71 can be immediately detected by the detection part 80 during the loading process, the delivery process, the retreat process, the receiving process, the unloading process, or the like, which makes it possible to quickly deal with an error appropriately.

The film forming apparatus 1 and the cleaning method according to the present disclosure are not limited to the above, and various modifications can be employed. For example, in the film forming apparatus 1, a sensor other than the torque sensor 81 or the magnetic sensor 82 may be applied to the detection part 80 provided at the transfer mechanism 72 itself. For example, the detection part 80 may be a strain sensor for detecting deformation of the support arm 73 in response to the shutter member 71 or deformation of the shutter member 71 itself. For another example, the detection part 80 may be a load sensor that is disposed at the support arm 73, the shaft portion 74, or the like to detect the change in the load caused by the shutter member 71.

Further, the film forming apparatus 1 does not necessarily include the transfer mechanism 72 including the support arm 73, the shaft portion 74, and the rotation device 75, and may include, e.g., a mechanism for linearly sliding the shutter member 71. Also in this case, the detection part 80 detects, as an indicator, the change in the load applied to a movable body (not shown) that slides together with the shutter member 71 or an operation part that operates the movable body. Accordingly, the controller 90 can reliably determine the presence or absence of the shutter member 71. Alternatively, by providing the magnetic sensor 82 at the movable body, the controller 90 can determine the presence or absence of the shutter member 71 based on the magnetic change of the magnetic sensor 82.

It is preferable to employ a configuration in which the shutter member 71 is taken out from the processing container 10 and replaced with a new shutter member 71 by a user. Further, the substrate processing system 100 may have a configuration in which the shutter member 71 is disposed between the processing chamber where the film forming apparatus 1 is disposed and the load port 150 (see also FIG. 1). Accordingly, in the substrate processing system 100, the shutter member 71 can be replaced without user's direct access to the processing container 10.

### Second Embodiment

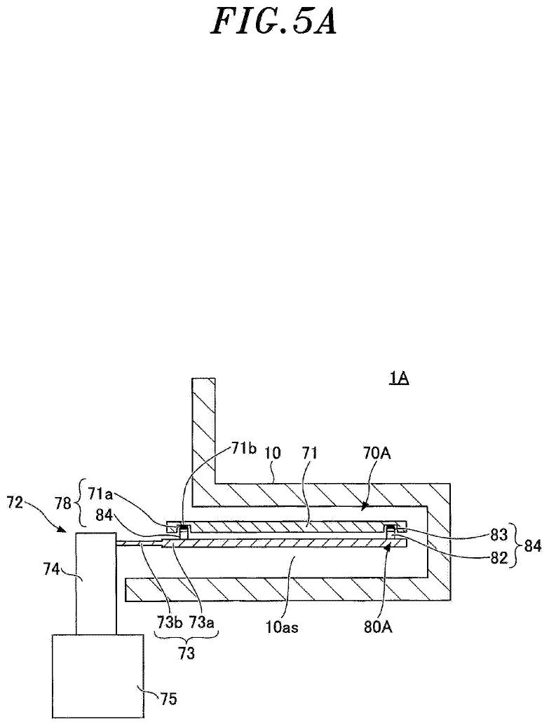

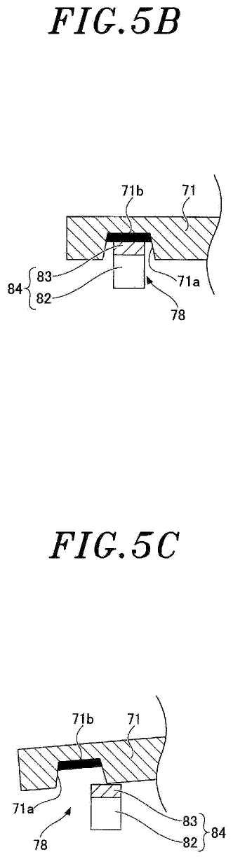

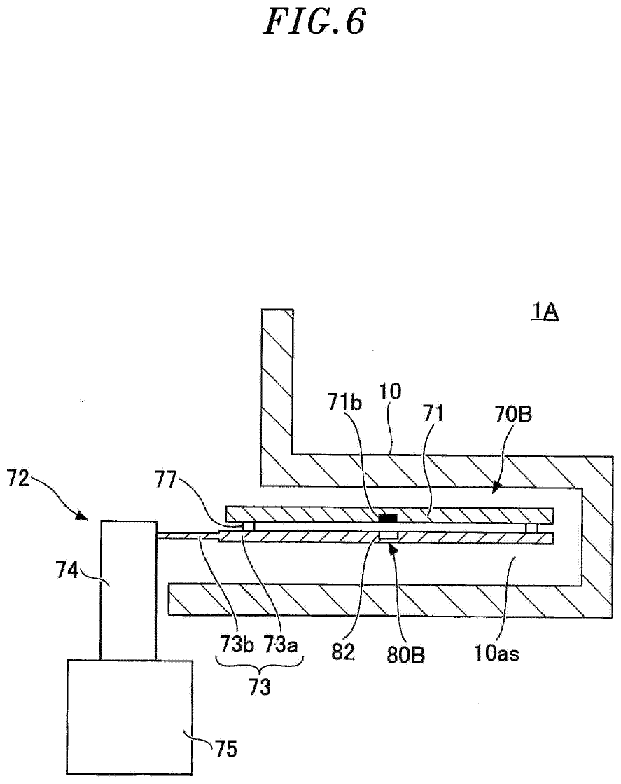

FIG. 5A is a schematic vertical cross-sectional view of a shutter mechanism part 70A of a film forming apparatus 1A according to a second embodiment. FIG. 5B is an enlarged vertical cross-sectional view in a state where the shutter member 71 is normally positioned. FIG. 5C is an enlarged vertical cross-sectional view in a state where the shutter member 71 is abnormally positioned. As shown in FIG. 5A, the shutter mechanism part 70A may include a detection part 80A for detecting the relative position of the shutter member 71 with respect to the support arm 73. For example, the support arm 73 includes a plurality of sensor terminals 84 in which a magnetic sensor 82 and a contact pad 83 are combined, instead of the contact terminal 77. The plurality of sensor terminals 84 are installed on the upper surface (the surface facing the shutter member 71) of the support main body 73a of the support arm 73, and each of the sensor terminals 84 includes the magnetic sensor 82 and the contact pad 83 that are sequentially stacked from the bottom. Similarly to the contact terminal 77 of FIG. 2, the contact pad 83 is made of a resin material that is softer than the shutter member 71.

On the other hand, the shutter member 71 is made of a non-magnetic material, and has a plurality of recesses 71a at locations to be in contact with the sensor terminals 84. As shown in FIG. 5B, the recess 71a is preferably formed in a tapered shape in which an opening side is large and the bottom surface (the inner side) is small. In other words, the shutter mechanism part 70A includes a positioning structure 78 for positioning the shutter member 71 by respectively inserting the plurality of sensor terminals 84 into the plurality of recesses 71a.

The shutter member 71 has chips 71b made of a magnetic material on the bottom surfaces of the recesses 71a. Accordingly, the magnetic sensors 82 of the sensor terminals 84 detects the magnetic change when the sensor terminals 84 are inserted into the recesses 71a and the magnetic sensors 82 become close to the chips 71b.

In the film forming apparatus 1A having the above-described shutter mechanism part 70A, when the shutter member 71 is normally supported by the transfer mechanism 72, the shutter member 71 and the support arm 73 are appropriately engaged by the positioning structure 78 (the recesses 71a and the sensor terminals 84). Therefore, it is possible to prevent the shutter member 71 from being misaligned with respect to the support arm 73 during the loading process, the unloading process, and the like.

Further, in the shutter mechanism part 70A, in the receiving process, when the shutter member 71 is lowered with respect to the support arm 73, the plurality of sensor terminals 84 of the support arm 73 are guided into the recesses 71a. When the sensor terminals 84 are inserted into the recesses 71a, the magnetic sensor 82 becomes close to the chips 71b and detects the magnetic change. Therefore, the controller 90 can determine that the sensor terminals 84 are normally inserted into the recesses 71a, that is, that the shutter member 71 and the support arm 73 are aligned to each other.

On the other hand, as shown in FIG. 5C, when the shutter member 71 is lowered but the sensor terminals 84 are not inserted into the recesses 71a, the magnetic sensor 82 is separated from the chips 71b, and thus does not detect the magnetic change. Hence, the controller 90 can determine that the sensor terminals 84 are not inserted into the recesses 71a, that is, the shutter member 71 and the support arm 73 are misaligned.

In this manner, in the film forming apparatus 1A, the relative position of the shutter member 71 with respect to the support arm 73 is detected by the detection part 80A, so that the shutter member 71 can be placed on the transfer mechanism 72 with higher precision. In particular, in the shutter mechanism part 70A, the shutter member 71 and the support arm 73 can be engaged by the positioning structure 78, so that the shutter member 71 can be more stably supported.

The film forming apparatus 1A according to the second embodiment does not necessarily have the above configuration, and may be variously modified. For example, in the detection part 80A of the shutter mechanism part 70A, it is unnecessary to replace all the contact terminals 77 with the sensor terminals 84, and the sensor terminals 84 may be applied to some of the contact terminals 77.

FIG. 6 is a schematic vertical cross-sectional view showing a shutter mechanism part 70B according to a modification. As shown in FIG. 6, the shutter mechanism part 70B has a chip 71b made of a magnetic material on a flat surface (bottom surface) of the shutter member 71 that faces the support arm 73. Further, the shutter mechanism part 70B has the contact terminal 77 instead of the sensor terminal 84, and also has the magnetic sensor 82 (a detection part 80B) at a location to face the chip 71b on the upper surface of the support arm 73. Although FIG. 6 shows a configuration including one chip 71b and one magnetic sensor 82, the shutter mechanism part 70B may have a plurality of chips 71b, and a plurality of magnetic sensors 82 at locations to face the chips 71b.

The magnetic sensor 82 disposed on the support arm 73 is located at a position that is not in contact with but close to the chip 71b, and thus detects the magnetic change when the shutter member 71 is supported by the support arm 73. On the other hand, when the shutter member 71 is misaligned with respect to the support arm 73, the magnetic sensor 82 is misaligned with respect to the chip 71b, and thus does not detect the magnetic change. In this manner, in the film forming apparatus 1A, the relative position of the shutter member 71 and the support arm 73 can be determined simply by detecting the chips 71b on the facing surface of the shutter member 71 using the magnetic sensor 82 installed at the support arm 73.

As described above, the film forming apparatus 1 according to the first aspect of the present disclosure includes the processing container 10, the sputtering targets T disposed in the processing container 10, the placing table 21 having a placing surface 211 on which the substrate (wafer W) is placed in the processing container 10, the shutter member 71 capable of covering the placing surface 211, the transfer mechanism 72 for loading/unloading the shutter member 71 with respect to the placing table 21, the detection part 80 that is disposed at the transfer mechanism 72 itself and detects an indicator related to the presence or absence of the shutter member 71, and the processing part (the controller 90) for determining the presence or absence of the shutter member 71 with respect to the transfer mechanism 72 based on the detection result of the detection part 80.

In the above film forming apparatus 1, it is possible to quickly and stably recognize the presence or absence of the shutter member 71 in each process of the cleaning by monitoring the shutter member 71 using the detection part 80 disposed at the transfer mechanism 72 itself. Accordingly, in the film forming apparatus 1, it is unnecessary to provide another detection part for detecting the movement of the shutter member 11 at the processing container 10, and the scaling down of the processing container 10 can be facilitated.

The transfer mechanism 72 includes the support arm 73 for supporting the shutter member 71 and the rotation device 75 for rotating the support arm 73, and the detection part 80 includes the torque sensor 81 that is disposed at the rotation sensor 75 to detect, as an indicator, the torque applied from the support arm 73 to the rotation device 75 during the rotation of the support arm 73. Accordingly, the controller 90 of the film forming apparatus 1 can detect the presence or absence of the shutter member 71 with high accuracy based on the torque applied to the rotation device 75.

The torque sensor 81 is disposed outside the processing container 10. Hence, the film forming apparatus 1 can further simplify the configuration of the transfer mechanism 72 in the processing container 10.

The shutter member 71 is made of a magnetic material, and the detection part 80 includes the magnetic sensor 82 that detects, as an indicator, the magnetic change that occurs when the shutter member 71 approaches. Accordingly, the controller 90 of the film forming apparatus 1 can detect the presence or absence of the shutter member 71 with high accuracy based on the magnetic change that occurs when the shutter member 71 is supported by the transfer mechanism 72.

The processing part (the controller 90) continues to determine the presence or absence of the shutter member 71 with respect to the transfer mechanism 72 during the transfer of the shutter member 71 by the transfer mechanism 72. Accordingly, in the film forming apparatus 1, it is possible to immediately detect an error such as falling of the shutter member 71 during the transfer thereof, and request a user to appropriately deal with the error.

Further, the processing part (the controller 90) determines the presence or absence of the shutter member 71 with respect to the transfer mechanism 72 at the time of delivering the shutter member 71 from the transfer mechanism 72 to the placing table 21 and at the time of allowing the transfer mechanism 72 to receive the shutter member 71 from the placing table 21. Accordingly, in the film forming apparatus 1, the presence or absence of the shutter member 71 can be quickly recognized at the time of delivering or receiving the shutter member 71, which makes it possible to retry the delivery process or the receiving process.

Further, the film forming apparatus 1A according to the second aspect of the present disclosure includes the processing container 10, the sputtering targets T disposed in the processing container 10, the placing table 21 having the placing surface 211 on which the substrate (wafer W) is placed in the processing container 10, the shutter member 71 capable of covering the placing surface 211, the transfer mechanism 72 for loading/unloading the shutter member 71 with respect to the placing table 21, the detection parts 80A and 80B disposed at the transfer mechanism 72 itself and configured to detect an indicator related to the position of the shutter member 71, and the processing part (the controller 90) for determining the position of the shutter member 71 with respect to the transfer mechanism 72 based on the detection results of the detection parts 80A and 80B. Also in this case, in the film forming apparatus 1A, the position of the shutter member 71 with respect to the transfer mechanism 72 can be quickly and stably detected.

The shutter member 71 is made of a non-magnetic material, and has one or more chips 71b made of a magnetic material on the facing surface facing the transfer mechanism 72. Each of the detection parts 80A and 80B includes the magnetic sensor 82 disposed at a location to face the chip 71b in the transfer mechanism 72. Accordingly, in the film forming apparatus 1A, it is possible to reliably recognize whether the position of the shutter member 71 with respect to transfer mechanism 72 is normal or abnormal (misalignment) based on the magnetic change of the magnetic sensor 82 with respect to the chip 71b.

The shutter member 71 has the recesses 71a formed on the facing surface and the chips 71b disposed at the inner sides of the recesses 71a. The detection part 80A includes the sensor terminals 84 provided with the magnetic sensors 82. The sensor terminals 84 protrude from the transfer mechanism 72, and thus can be inserted into the recesses 71a. Accordingly, in the film forming apparatus 1A, the sensor terminals 84 and the recesses 71a can be engaged with each other, thereby transferring the shutter member 71 more safely.

The third aspect of the present disclosure provides the cleaning method for the film forming apparatus 1 including the processing container 10, the sputtering targets T disposed in the processing container 10, and the placing table 21 having the placing surface 211 on which the substrate (wafer W) is placed in the processing container 10. The cleaning method includes loading/unloading the shutter member 71 capable of covering the placing surface 211 with respect to the placing table 21 by the transfer mechanism 72, detecting an indicator related to the presence or absence of the shutter member 71 by the detection part 80 disposed at the transfer mechanism 72 itself, and determining the presence or absence of the shutter member 71 with respect to the transfer mechanism 72 based on the detection result of the detection part 80.

The fourth aspect of the present disclosure provides the cleaning method for the film forming apparatus 1 including the processing container 10, the sputtering targets T disposed in the processing container 10, and the placing table 21 having the placing surface 211 on which the substrate (wafer W) is placed in the processing container 10. This cleaning method includes loading/unloading the shutter member 71 capable of covering the placing surface 211 with respect to the placing table 21 by the transfer mechanism 72, detecting an indicator related to the presence or absence of the shutter member 71 by the detection parts 80A and 80B disposed at the transfer mechanism 72 itself, and determining the presence or absence of the shutter member 71 with respect to the transfer mechanism 72 based on the detection results of the detection parts 80A and 80B.

Also in the cleaning methods of the film forming apparatus 1 according to the third and fourth aspects described above, it is possible to quickly and stably detect the shutter member 71 that covers the placing surface 211 of the placing table 21.

It should be noted that the film forming apparatus 1 according to the embodiments of the present disclosure are illustrative in all respects and are not restrictive. The above-described embodiments can be variously modified and improved without departing from the scope of the appended claims and the gist thereof. The above-described embodiments may include other configurations without contradicting each other, and may be combined without contradicting each other.

This application claims priority to Japanese Patent Application No. 2021-108131, filed on Jun. 29, 2021, the entire contents of which are incorporated herein by reference.

### DESCRIPTION OF REFERENCE NUMERALS

1, 1: film forming apparatus
10: processing container
21: placing table
211: placing surface
71: shutter member
71a:recess
71b: chip
72: transfer mechanism
73: support arm
74: shaft portion
75: rotation device
80, 80A, 80B: detection part
81: torque sensor
82: magnetic sensor
84: sensor terminal
90: controller
W: wafer

1. A film forming apparatus comprising:
a processing container;
a sputtering target disposed in the processing container;
a placing table having a placing surface on which a substrate is placed in the processing container;
a shutter member configured to cover the placing surface;
a transfer mechanism configured to load and unload the shutter member into and from the placing table;
a detection part disposed at the transfer mechanism itself, the detection part configured to detect an indicator related to a presence or an absence of the shutter member; and
a processing part configured to determine the presence or the absence of the shutter member with respect to the transfer mechanism based on a detection result of the detection part.

2. The film forming apparatus of claim 1, wherein the transfer mechanism includes a support arm configured to support the shutter member and a rotation device configured to rotate the support arm, and the detection part includes a torque sensor disposed at the rotation device and configured to detect, as the indicator, a torque applied from the support arm to the rotation device when the support arm rotates.

3. The film forming apparatus of claim 2, wherein the torque sensor is disposed outside the processing container.

4. The film forming apparatus of claim 1, wherein the shutter member is made of a magnetic material, and the detection part includes a magnetic sensor configured to detect, as the indicator, a magnetic change that occurs when the shutter member approaches.

5. The film forming apparatus of claim 1, wherein the processing part continues to determine the presence or the absence of the shutter member with respect to the transfer mechanism during transfer of the shutter member by the transfer mechanism.

6. The film forming apparatus of claim 1, wherein the processing part determines the presence or the absence of the shutter member with respect to the transfer mechanism at a time of delivering the shutter member from the transfer mechanism to the placing table and at a time of allowing the transfer mechanism to receive the shutter member from the placing table.

7. A film forming apparatus comprising:
a processing container,
a sputtering target disposed in the processing container;
a placing table having a placing surface on which a substrate is placed in the processing container;
a shutter member configured to cover the placing surface;
a transfer mechanism configured to load and unload the shutter member into and from the placing table;
a detection part disposed at the transfer mechanism itself, the detection part configured to detect an indicator related to a position of the shutter member; and
a processing part configured to determine the position of the shutter member with respect to the transfer mechanism based on a detection result of the detection part.

8. The film forming apparatus of claim 7, wherein the shutter member is made of a non-magnetic material, and has one or more chips made of a magnetic material on a facing surface facing the transfer mechanism, and the detection part includes a magnetic sensor disposed at a location to face a chip from the one or more chips in the transfer mechanism.

9. The film forming apparatus of claim 8, wherein the shutter member has a recess formed on the facing surface, and the chip is disposed at an inner side of the recess,
the detection part includes a sensor terminal having the magnetic sensor, and
the sensor terminal protrudes from the transfer mechanism to be inserted into the recess.

10. A method for cleaning a film forming apparatus, the film forming apparatus including a processing container, a sputtering target disposed in the processing container, and a placing table having a placing surface on which a substrate is placed in the processing container, wherein the method comprises:
loading/unloading, by a transfer mechanism, a shutter member configured to cover the placing surface into/from the placing table;
detecting an indicator related to a presence or an absence of the shutter member by a detection part disposed at the transfer mechanism itself; and
determining the presence or the absence of the shutter member with respect to the transfer mechanism based on a detection result of the detection part.

11. A method for cleaning a film forming apparatus, the film forming apparatus including a processing container, a sputtering target disposed in the processing container, and a placing table having a placing surface on which a substrate is placed in the processing container, wherein the method comprises:
loading/unloading, by a transfer mechanism, a shutter member configured to cover the placing surface into/from the placing table;
detecting an indicator related to a presence or an absence of the shutter member by a detection part disposed at the transfer mechanism itself; and
determining the presence or the absence of the shutter member with respect to the transfer mechanism based on a detection result of the detection part.
